(19) United States
(12) Patent Application Publication
(10) Pub. No.: US 2019/0195715 A1
(43) Pub. Date: Jun. 27, 2019

(54) Smooth Signal Filtering

(71) Applicant: Torque And More GmbH, Starnberg (DE)

(72) Inventor: Lutz May, Starnberg (DE)

(21) Appl. No.: 16/307,731

(22) PCT Filed: Jun. 6, 2017
(86) PCT No.: PCT/EP2017/063710

§ 371 Date: Dec. 6, 2018

(30) Foreign Application Priority Data
Jun. 6, 2016 (EP) 16173193.0

(51) Int. Cl. G01L 5/24; H03H 11/04

(52) U.S. Cl. CPC G01L 5/24; H03H 11/04

(57) ABSTRACT

A signal filtering device for filtering a series of values includes a first signal transmission branch with a signal filter. The signal filter is configured to filter the series of values. The filtering device also includes a second signal transmission branch passing a value from the signal input interface to the signal output interface. The signal filtering device further includes a signal input interface receiving the series of values and providing the received values to the first signal transmission branch and the second signal transmission branch, a signal output interface outputting a value, a switch, and a switch control device. The switch is configured to selectively connect one of the first signal transmission branch and the second signal transmission branch to the signal output interface. The switch control device is connected to the signal input interface and configured to receive the series of values and to control a switching operation of the switch based on the received series of values.

### TECHNICAL FIELD

The present invention relates to signal filtering. In particular, the disclosure relates to a signal filtering device, to a method for filtering a signal, and to a power torque tool with such a signal filtering device.

### BACKGROUND OF THE INVENTION

Signal filtering approaches may be applied to series of signal values in order to process the individual values, for example in order to reduce the noise of the series of signal values. For example, measured force values may be applied to signal filtering.

Generally speaking, force measuring is important for many industrial applications, in particular for arrangements being dynamically impacted by a force. Applied forces may be pressure forces as well as moments like torque and bending impact. An exemplary application for torque is a shaft for a vehicle or a gear being arranged between a motor and a wheel. Furthermore, it might be required to determine the forces applied to a shaft of a power tool.

The torque applied to the shaft may be measured by applying various approaches.

When using a standard (and easy to implement) signal filter algorithms then there will be a noticeable delay in the filtered signal with reference to the original signal. For example, if the used filter algorithm calculates the average of ten successive input signal values, the resulting output signal is delayed by ten values or periods (in comparison to the original signal).

### SUMMARY OF THE INVENTION

It may be seen as an object of the present invention to reduce the delay of a filter output signal.

This object is solved by the subject matter of the independent claims, further embodiments are incorporated in the dependent claims and in the following description.

According to a first aspect, a signal filtering device is provided for filtering a series of values, which might be referred to as input signal or input signal values. The signal filtering device comprises a first signal transmission branch with a signal filter, wherein the signal filter is configured to filter the series of values, a second signal transmission branch for passing a value from the signal input interface to the signal output interface, a signal input interface, a signal output interface, a switch, and a switch control device. The signal input interface is configured to receive the series of values and to provide the received values to the first signal transmission branch and to the second signal transmission branch. The signal output interface is configured to output a value, in particular the output value of the signal filtering device either from the first or the second signal transmission branch in accordance with the principles described herein. The switch is configured to selectively connect one of the first signal transmission branch and the second signal transmission branch to the signal output interface, and the switch control device is connected to the signal input interface and is configured to receive the series of values and to control a switching operation of the switch based on the received series of values.

In the context of this disclosure, the series of values may generally be referred to as an input signal. The input signal may particularly be a time-discrete signal sampled with a given sampling rate having a correspond signal period.

The switching operation of the switch specifically relates to a state of the switch, i.e., whether the switch connects the first signal transmission branch or the second signal transmission branch to the signal output interface. In other words, the switch has at least two switching states, wherein in a first switching state, the switch connects the first signal transmission branch to the signal output interface and in a second switching state, the switch connects the second signal transmission branch to the signal output interface. However, the switch may also have a third switching state in which none of the transmission branches is connected to the output interface.

The signal filter may be any type of signal filter and may implement any filter algorithm. The signal filtering is applied to the series of values transmitted from the signal input interface to the first signal transmission branch, i.e., to the signal filter.

The second signal transmission branch is a direct and/or uninterrupted or continuous connection from the signal input interface to the switch, such that the switch passes through a signal from the signal input interface to the signal output interface in case the switch is in a corresponding switching state, i.e., in the second switching state referred to above.

The switch is configured to pass either the first signal transmission branch or the second signal transmission branch to the signal output interface, such that depending on the course of the values applied to the signal input interface, the one or the other signal transmission branch is passed through to the signal output interface.

The switching operation, i.e., bringing the switch into one of its possible states, is controlled by the switch control device. The switch control device is also connected to the signal input interface and receives the original (unfiltered) series of values. Thus, the switch control device can generate appropriate control commands for controlling the state of the switch based on the course of the values applied to the signal input interface.

According to an embodiment, the switch control device is configured to determine a signal value change within a predetermined period of time and to control the switching operation of the switch based on the determined signal value change.

In this embodiment, the switch control device monitors, for example, how quick the signal value at the signal input interface changes, i.e., it determines a change rate of the signal value. For determining the change rate, two values of the input signal are considered: the value at the beginning of the predetermined period of time and the value at the end of the predetermined period of time. Thus, a change rate or a signal value change of the input signal within the predetermined period of time is determined. However, the absolute value of the input signal (the signal present at the signal input interface) is of no relevance for determining the change rate; only the signal value change is considered. This signal value change is determined in a sliding window manner.

This approach may allow to distinguish between signal value changes resulting from noise and signal value changes resulting from effective changes of an input signal. It may be assumed, that signal value changes resulting from noise have a high frequency, but are limited in their amplitude, i.e., do not exceed an application specific threshold value, which may in particular be a noise signal amplitude. On the other hand, the switch control device will recognize effective changes of the input signal, as these effective changes result in a signal value change which exceeds a threshold value. This threshold value may be varied and set individually for each application environment. However, the threshold value of the signal value change is indicative for the maximum amplitude of the noise signal expected in the given application environment. In case, the signal value change exceeds the threshold value, it is assumed that the signal value change results from an effective change of the input signal.

According to a further embodiment, the predetermined period of time is a multitude of a period of a sampling rate of the series of values.

In this embodiment, the signal filtering device is independent of the sampling rate of the input signal as a time duration (and not the period of the time-discrete input signal samples) is the relevant parameter for determining the change rate or signal value change.

According to a further embodiment, the switch control device is configured to compare the determined signal value change within the predetermined period of time with a threshold value and to control the switch such that in a first switching state the first signal transmission branch is connected to the signal output interface if the threshold value is not exceeded and to control the switch such that in a second switching state the second signal transmission branch is connected to the signal output interface if the threshold value is exceeded.

If the threshold value is exceeded, it is assumed that the input signal change results from an effective change of the signal value while it is assumed that the input signal change results from noise if the threshold value is not exceeded. An effective change of the signal value is a change that is not noise, but an actual signal value change.

Thus, if the threshold value is not exceeded (i.e., signal value changes result from noise), the input signal is filtered by the filter in the first signal transmission branch. Especially, in this case, a smoothing of the input signal (noise cancellation or noise suppression) is achieved as a result of the filter algorithm and the influence of noise to the output signal (that is the signal supplied at the signal output interface) is reduced, eliminated, or almost eliminated.

According to a further embodiment, the switch control device is configured to transmit a current input signal value to the signal filter prior to switching the switch from the second switching state to the first switching state.

In this embodiment, the filter and particularly its memory or filter register for storing past signal values as a basis for the filtering operation is overwritten at least by the current input signal value. The filtering operation of the filter requires calculation, and time for carrying out this calculation. Thus, there is a delay between the output values of the filter in the first signal transmission branch and the signal values in the second signal transmission branch (or the original signal), as no active component or processing device is used in the second signal transmission branch.

Without any compensation, input signal values might be output twice when switching from the second switching state to the first switching state. In the second signal transmission branch, the input signal value is directly passed to the switch while in the first signal transmission branch, there is at least the signal filter positioned and requires some time for its operation and calculation.

According to a further embodiment, the switch control device is configured to clear the signal filter prior to switching the switch from the second switching state to the first switching state, so that filtering is applied to newly received input signal values only.

In this embodiment, past data is cleared from the signal filter in order to cancel historic and delayed data when switching from the second switching state to the first switching state. Thus, the signal filter works on current data and no signal value overlap at the signal output interface occurs.

In order to provide a quick filter, the input signal value may be applied throughout the entire operation of the signal filtering device to the first and second signal branch in parallel. A decision on which of these branches to pass through to the output signal interface is taken by the switch control device. In other words, the signal filter executes the filter algorithm in a continuous operation, but the output of the signal filter is not continuously output to the signal output interface. However, even though the signal filter operates continuously, under specific circumstances, the signal values used by the signal filter are changed, especially when switching from the second switching state to the first switching state.

For example, the signal filter may work by building the average of a number of successive past measurement values, for example ten measurement values. Consequently, the resulting output signal is delayed by this number of values in comparison to the original input signal. This delay may be undesired, especially for time-critical applications which require accurate and quick (real-time) acquiring of data even if a signal filter is applied or used.

The signal filtering device as described herein enables filtering an input signal and also recognizing if an input signal change results from an effective signal change (and not from noise). If the input signal change results from an effective signal change, the input signal is passed through to the switch and to the output interface (the switch is in the second switching state) and if the input signal change results from noise, the input signal is filtered (the switch is in the first switching state). Furthermore, in order to avoid outputting outdated signal values from the signal filter when changing from the second switching state to the first switching state, the current input signal value received by the switch control device is transmitted to the signal filter and is used as a basis for the filter algorithm.

According to a further embodiment, the switch control device is configured to determine the signal value change within a predetermined period of time in an iterative manner.

The switch control device continuously monitors the course of the input signal value and repeatedly determines the signal value change within the predetermined period of time. The predetermined period of time may be set to a specific value depending on application specifications of the signal filtering device and its environment. The predetermined period of time may be equal to or lower than the period resulting from the sampling rate of the input signal values.

According to a further aspect, a method for filtering a series of values is provided. The method comprises the following steps: receiving the series of values, filtering the series of values, monitoring the series of values and determining a signal value change within a predetermined period of time, passing through the received series of values or the filtered series of values depending on the determined signal value change within the predetermined period of time.

It should be understood that the explanation provided herein with reference to the signal filtering device applies in an analogue manner to the method for filtering a series of values. Therefore, those details are not repeated here. Instead, the person skilled in the art will understand that the function of the signal filtering device may be implemented as method steps and vice versa.

According to an embodiment, the method further comprises the step comparing the determined signal value change within the predetermined period of time with a threshold value and passing through the filtered series of values if the threshold value is not exceeded and passing through the received series of values if the threshold value is exceeded.

According to a further embodiment, the method further comprises the step transmitting a current input signal value of the received series of values to a signal filter in case the received series of values is passed through and if, additionally, the signal value change falls below the threshold value, which results in passing through the filtered series of values.

According to a further embodiment, the method further comprises the step clearing a signal filter if the signal value change falls below the threshold value, so that filtering is applied to newly received signal values only.

According to a further aspect, a power torque tool is provided and configured to apply a force to an object. The power torque tool comprises a signal filtering device as described herein.

The signal filtering device may be configured to determine the power applied by the power torque tool to the object. By using the signal filtering device described herein, there is no or almost no delay in the output signal of the signal filtering device and it may be determined in real time and without any excessive delay when to release a driving force. This may be the case if a predetermined threshold value of the force applied to the object is reached and applying additional force or torque to the object is undesired or may even result in possible material damage of the object.

According to an embodiment, the power torque tool comprises a driving shaft configured to rotate and to apply a torque force to the object, and a force measuring device, configured to measure a force applied to the driving shaft. The signal filtering device is connected to the force measuring device and is configured to receive a force measuring signal from the force measuring device and to filter the force measuring signal.

Thus, the signal filtering device provides the force measuring signal with less or no delay to a controller of the power torque tool such that the controller stops rotation of the driving shaft. The signal filtering device described herein enables a quick reaction of the power torque tool responsive to reaching a threshold value of the applied force.

It should be understood that the signal filtering device may be used in any environment where signal filtering with low delay is desired. For example, it may be used in a gear box of a vehicle to determine the torque applied by an engine and transmitted to the wheels of the vehicle. Other applications may be easily found by the person skilled in the art.

### BRIEF DESCRIPTION OF THE DRAWINGS

In the following for further illustration and to provide a better understanding of the present invention exemplary embodiments are described in more detail with reference to the enclosed drawings, in which

FIG. 1 schematically shows a signal filtering device according to an exemplary embodiment of the invention,

FIG. 2 schematically shows an input signal, a filtered signal, and an output signal of a signal filtering device according to an exemplary embodiment of the invention,

FIG. 3 schematically shows an input signal, a switch state, and an output signal of a signal filtering device according to an exemplary embodiment of the invention,

FIG. 4 schematically shows a power torque tool according to an exemplary embodiment of the invention.

### DETAILED DESCRIPTION OF EXEMPLARY EMBODIMENTS

The following detailed description is merely exemplary in nature and is not intended to limit the invention or the application and uses of the invention. Furthermore, there is no intention to be bound by any theory presented in the preceding background or the following detailed description.

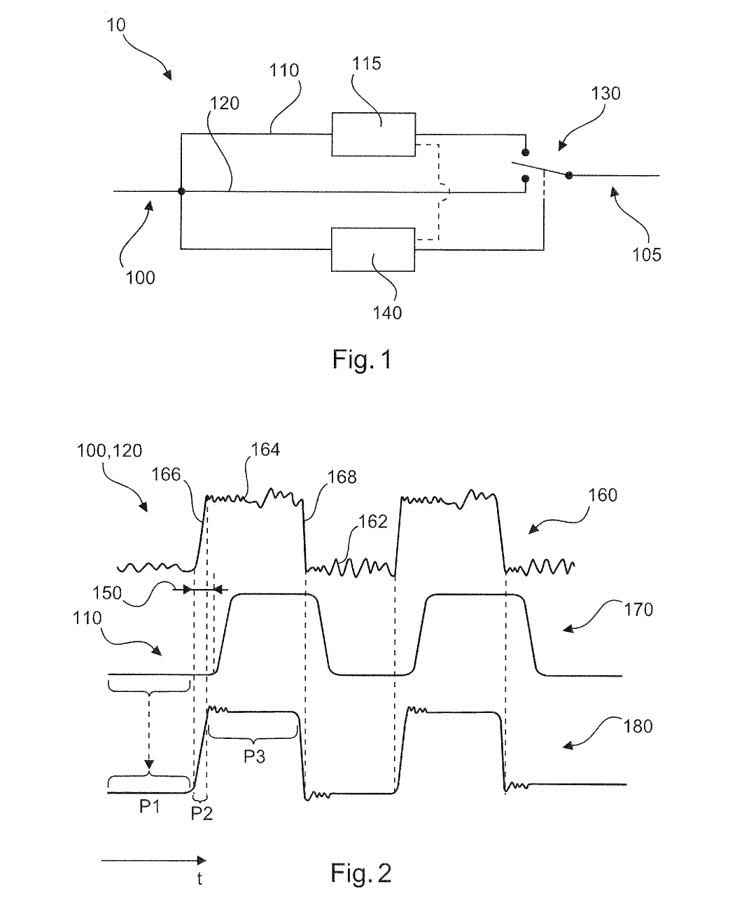

FIG. 1 shows a signal filtering device 10. The signal filtering device 10 comprises a signal input interface 100 for receiving an input signal and a signal output interface 105 for outputting a processed signal. The signal filtering device 10 comprises two signal transmission branches, namely a first signal transmission branch 110 with a signal filter 115 and a second signal transmission branch 120 which substantially passes or loops through the signal from the input interface 100 to the switch 130.

The switch 130 is configured to selectively pass through either the first signal transmission branch 110 or the second signal transmission branch 120 to the signal output interface 105. However, both signal transmission branches receive the input signal from the signal input interface continuously during the operation of the signal filtering device 10 and only the output of the branches 110, 120 is selectively passed through to the output interface 105.

The switch 130 is configured to take at least two different switching states: in a first switching state, the switch is in the upper position and connects the first signal transmission branch 110 to the output interface 105 while in a second switching state, the switch 130 is in the lower position and connects the second signal transmission branch 120 to the output interface 105. The switch 130 may also have a third switching state in which none of the first or second signal transmission branches is passed through.

The switch 130 is controlled by switch control device 140. Switch control device 140 receives the input signal from the signal input interface 100 and controls the switching state of the switch 130 depending on the input signal value, especially depending on an input signal change rate.

The switch control device 140 is configured to compare the determined signal value change or signal value change rate within a predetermined period of time (i.e., the absolute value of the signal value change within the period of time, difference between signal value at the end of the period of time and signal value at the beginning of the period of time) with a threshold value and to control the switch 130 such that in a first switching state the first signal transmission branch 110 is connected to the signal output interface 105 if the threshold value is not exceeded and to control the switch 130 such that in a second switching state the second signal transmission branch 120 is connected to the signal output interface 105 if the threshold value is exceeded.

If the threshold value is exceeded, it is assumed that the input signal change results from an effective change of the signal value while it is assumed that the input signal change results from noise if the threshold value is not exceeded. An effective change of the signal value is a change that is not noise, but an actual signal value change.

Thus, if the threshold value is not exceeded (i.e., signal value changes result from noise), the input signal is filtered by the signal filter 115 in the first signal transmission branch 110. Especially, in this case, a smoothing of the input signal (noise cancellation or noise suppression) is achieved as a result of the filter algorithm and the influence of noise to the output signal (that is the signal supplied at the signal output interface) is reduced, eliminated, or almost eliminated.

The switch control device 140 is communicatively coupled with the signal filter 115 in order to transmit a current signal value received from the signal input interface 100 to the signal filter 115 prior to switching the switch 130 from the second switching state to the first switching state.

Those of skill in the art would further that the various illustrative logical and/or functional blocks/tasks/steps, modules, circuits, and algorithm steps described in connection with the embodiments disclosed herein may be implemented as electronic hardware, computer software, or combinations of both. Some of the embodiments and implementations are described above in terms of functional and/or logical block components (or modules) and various processing steps. However, it should be appreciated that such block components (or modules) may be realized by any number of hardware, software, and/or firmware components configured to perform the specified functions. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. For example, an embodiment of a system or a component may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments described herein are merely exemplary implementations.

Referring again to FIG. 1, the signal filtering device is a hardware device that carries out instructions to perform the functions described herein, in particular the functions of the signal filter 115 and of the switch control device 140.

The signal filter 115 includes one or more memory units (not shown) that store electronic data (the input signal values) and computer programs, i.e., instructions for processing the stored data. For example, the memory units may be flash memory, spin-transfer torque random access memory (STT-RAM), magnetic memory, phase-change memory (PCM), dynamic random access memory (DRAM), or other suitable electronic storage media. In the example provided, the memory units store filter logic with instructions that cooperate with a processor (not shown) of filter device 115 to perform operations described herein. In some embodiments, the processor may include one or more central processing units (“CPUs”), a microprocessor, an application specific integrated circuit (“ASIC”), a microcontroller, and/or other suitable device. Furthermore, signal filter 115 may utilize multiple hardware devices as is also appreciated by those skilled in the art.

The various illustrative logical and functional blocks, modules, and circuits described in connection with the embodiments disclosed herein may be implemented or performed with a processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor, for example, a general-purpose processor, may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. The word “exemplary” is used exclusively herein to mean “serving as an example, instance, or illustration.” Any embodiment described herein as “exemplary” is not necessarily to be construed as preferred or advantageous over other embodiments.

The steps of a method or algorithm or the functions described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC.

FIG. 2 schematically shows three exemplary signal courses and the relation with respect to one another in terms of signal filtering and time (delay). The upper signal 160 represents the input signal applied to the signal input interface 100. The middle signal 170 represents the signal filtered by the signal filter 115 and provided to switch 130. The lower signal 180 shows the resulting signal at the output interface 105 provided as a combination of the filtered signal 170 and the original input signal 160 that is transmitted through the second signal transmission branch 120 to the switch 130.

The input signal is schematically shown as a square wave signal. However, it is noted that any signal type or signal shape can be used. The input signal of FIG. 2 is characterized by substantially constant sections at a first signal level 162 and a second signal level 164 with a rising edge 166 and a falling edge 168 in between.

The input signal is filtered in order to reduce noise. In FIG. 2, noise is indicated by the signal value fluctuations if the signal nominally is at first and second signal levels 162, 164. However, noise may also be included in the rising and falling edges.

Filtering results in a time delay 150 between signals 160 and 170, see gap between the respective first rising edges of signals 160 and 170. This time delay may be undesired. The time delay (the middle signal 170 is shifted to the right in comparison to upper signal 160) results from the filtering operation of signal filter 115. The lower signal 180 is substantially the same as the upper signal 160 with no or almost no time delay.

In order to eliminate or minimize the time delay 150 of the resulting signal 180 with respect to the original input signal, the filtered signal of the first signal transmission branch 110 and the looped through signal of the second signal transmission branch 120 are combined or switched through to the output interface 105 as described herein.

This switching process might be best understood when referring to the different phases of the output signal 180.

In a first phase P1, the filtered signal 170 is output to the output interface 105. In other words, the switch 130 is in the first switching state and connects the first signal transmission branch 110 to the output interface 105. In phase P1, the input signal is at a substantially constant value and contains noise, but does not effectively change. This is applied to the first and the second signal levels 162 and 164. The input signal is filtered as the changes resulting from noise do not exceed a signal change threshold value, which might be variably set depending on specific applications.

When the input signal 160 transitions from first signal level 162 to second signal level 164, a rising edge 166 effectively changes the signal value and phase P2 starts (at the beginning of a rising edge of the input signal or as soon as the rising edge exceeds the signal change threshold value). This rising edge of the input signal value exceeds the signal change threshold value and will thus be recognized as an effective change of the signal value. When recognizing the effective change of the input signal value, switch control device 140 controls the switch to connect the second signal transmission branch 120 to the output interface, such that the input signal value is looped through without any time delay. The rising edge will be immediately output at the output interface 105 without the time delay 150 of the filtered signal 170. In other words, in phase P2 a quick input signal value change is detected (input signal value exceeds the threshold value), and the switch 130 is changed to second switching state so that the signal of second signal transmission branch 120 is output.

It is noted that this also applies to the falling edge 168 when transitioning from signal level 164 back to signal level 162.

Once the input signal achieves the signal level 164, the signal value will not further increase, i.e., the signal change threshold value is not exceeded any more. In this case, the switch control device 140 controls the switch 130 to change to the first switching state so that the signal of the first (filtered) filtered transmission branch 110 is output.

This is referred to as phase P3, in which the signal value change is below or equal to the threshold value. However, at the beginning of phase P3, the current signal value of the second signal transmission branch 120 is transmitted to the signal filter 115 and the signal filter 115 starts filtering operation with this current signal value. Furthermore, any existing input signal values stored in the memory of the signal filter 115 are cleared or, at least, not considered for further filter operation. This eliminates effects of past (delayed) signal values in the first signal transmission branch and filtering is started with the current input signal value.

However, at the beginning of phase P3, the input signal may be looped through via the second signal transmission branch 120 until it is determined by the switch control device 140 that the threshold value is not exceeded anymore and the signal from the first signal transmission branch 110 is output. Furthermore, at the beginning of phase P3, signal filter 115 need to reactivate, which may also cause some decreasing noise at the beginning of phase P3.

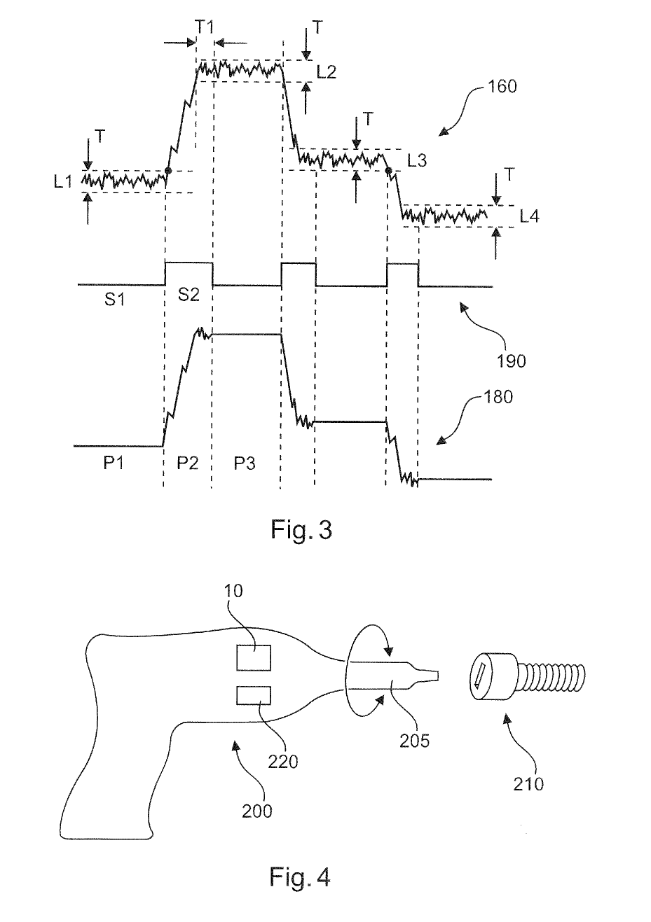

FIG. 3 shows input signal 160, switch state 190, and the combined output signal 180. The input signal can have several different levels L1, L2, L3, L4. As can be seen, input signal fluctuates due to noise. The switch state signal 190 indicates the state of switch 130 shown in FIG. 1. In state S1, the switch 130 connects the first signal transmission branch 110 to the signal output interface 105, so that the filtered signal is output. In state S2, switch 130 connects the second signal transmission branch 120 to the signal output interface 105 and the input signal is directly looped through.

The combined output signal 180 results from the state of switch 130 and from transmitting the current signal value of the second signal transmission branch 120 to the signal filter 115 so that the signal filter 115 starts the filtering operation with this current signal value.

A threshold range T is used to distinguish between noise and an effective signal value change. An effective signal value change is considered to be present if the signal value exceeds threshold range T, i.e., if the signal value changes from one signal level L1, L2, L3, L4 to another signal level. As long as the signal value fluctuates within threshold range T, it is assumed that this change results from noise. If the signal value exceeds the upper limit or the lower limit of the threshold range T, it is assumed that this results from an effective signal value change, i.e., from a signal level change, and the input signal is looped through via the second signal transmission branch 120.

It is noted that the threshold range T is not a constant range, as one might get the impression from FIG. 3. Threshold range T is shown with horizontal dashed lines as upper and lower limit, respectively. However, the threshold range is adapted with every newly captured signal value. For example, if the threshold range is +/−200 mV and the last captured signal value is 5V, the next signal value is assumed to be noise if it is within the range of 4.8V and 5.2V (and to be an effective signal value change if it is above or below). If the next signal value is 5.1V, the threshold range changes to 4.9V to 5.3V. In other words, the threshold range T is not a constant corridor around the signal levels, but the threshold range is determined with every newly captured signal value. In FIG. 3, the corridor with the constant upper and lower limit is shown for ease of understanding.

As soon as the input signal 160 exceeds the threshold value, switch 130 changes from state S1 to state S2 and the input signal is directly looped through to the signal output interface 105. Once the input signal 160 reaches the next signal level L2 and only noise is added to the signal value, it may take some time to recognize that no effective signal value change happens. This time is shown at T₁. If the signal value is within the threshold range T for time T₁, the switch 130 will change state from S2 to S1, and the input signal is filtered.

Summing up, as long as the input signal value is within the threshold range T, the switch 130 is in state S1 and the input signal 160 is filtered and output to the signal output interface 105. This is referred to as phase P1. If the input signal 160 leaves the threshold range T, switch 130 changes from state S1 to state S2 and the input signal 160 is directly looped through to the signal output interface 105 without any filtering. This is phase P2. After the input signal changed its level and the input signal value again is within the threshold range T for a given period of time T₁, the switch 130 changes from state S2 to state S1 and the input signal is filtered prior to being output to signal output interface 105. This is phase P3. These phases are repeated depending on the input signal value change.

FIG. 4 describes a power torque tool 200 with a driving shaft 205. The driving shaft 205 is configured to apply a force to object 210, for example a screw. The driving shaft 205 rotates and applies a torque force to object 210. The power torque tool 200 comprises a force measuring device 220 that is arranged to measure the force applied to the driving shaft 205. The force induced in the driving shaft 205 results from a driving unit (not shown) and a resistance of the 210. If the force induced in the driving shaft 205 is equal to or exceeds a threshold value, it is assumed that the object is fastened appropriately. In this case, the driving unit must stop driving the driving shaft in order to prevent material damage of the object 210. It is advantageous to detect in an almost real-time manner with as less delay as possible if this condition is achieved. This is enabled by the signal filtering device which, on the one hand, filters the input signal and, on the other hand, passes through effective signal changes with minimum delay.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language. The sequence of the text in any of the claims does not imply that process steps must be performed in a temporal or logical order according to such sequence unless it is specifically defined by the language of the claim. The process steps may be interchanged in any order without departing from the scope of the invention as long as such an interchange does not contradict the claim language and is not logically nonsensical.

Furthermore, depending on the context, words such as “connect” or “coupled to” used in describing a relationship between different elements do not imply that a direct physical connection must be made between these elements. For example, two elements may be connected to each other physically, electronically, logically, or in any other manner, through one or more additional elements.

While at least one exemplary embodiment has been presented in the foregoing detailed description, it should be appreciated that a vast number of variations exist. For example, although the disclosed embodiments are described with reference to a flight control computer of an aircraft, those skilled in the art will appreciate that the disclosed embodiments could be implemented in other types of computers that are used in other types of vehicles including, but not limited to, spacecraft, submarines, surface ships, automobiles, trains, motorcycles, etc. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

### LIST OF REFERENCE SIGNS

10 Signal filtering device
100 signal input interface
105 signal output interface
110 first signal transmission branch
115 signal filter
120 second signal transmission branch
130 switch
140 switch control device
150 time delay between input signal and signal filter output
160 input signal
162 first signal level
164 second signal level
166 rising edge
168 falling edge
170 filtered signal
180 output signal
190 switch state
200 power torque tool
205 driving shaft
210 object
220 force measuring device

1-13. (canceled)

14. A signal filtering device for filtering a series of values, comprising:
a signal input interface;
a signal output interface outputting a value;
a first signal transmission branch with a signal filter, the signal filter configured to filter the series of values;
a second signal transmission branch passing a value from the signal input interface to the signal output interface, wherein the signal input interface receiving the series of values and providing the received values to the first signal transmission branch and the second signal transmission branch;
a switch configured to selectively connect one of the first signal transmission branch and the second signal transmission branch to the signal output interface; and
a switch control device connected to the signal input interface and configured to receive the series of values, the switch control device configured to control a switching operation of the switch based on the received series of values.

15. The signal filtering device of claim 14, wherein the switch control device is configured to determine a signal value change within a predetermined period of time and to control the switching operation of the switch based on the determined signal value change.

16. The signal filtering device of claim 15, wherein the predetermined period of time is a multitude of a period of a sampling rate of the series of values.

17. The signal filtering device of claim 15, wherein the switch control device is configured to compare the determined signal value change within the predetermined period of time with a threshold value and to control the switch such that in a first switching state the first signal transmission branch is connected to the signal output interface if the threshold value is not exceeded and to control the switch such that in a second switching state the second signal transmission branch is connected to the signal output interface if the threshold value is exceeded.

18. The signal filtering device of claim 17, wherein the switch control device is configured to transmit a current input signal value to the signal filter prior to switching the switch from the second switching state to the first switching state.

19. The signal filtering device of claim 17, wherein the switch control device is configured to clear the signal filter prior to switching the switch from the second switching state to the first switching state, so that filtering is applied to newly received input signal values only.

20. The signal filtering device of claim 14, wherein the switch control device is configured to determine the signal value change within a predetermined period of time in an iterative manner.

21. A method for filtering a series of values, comprising:
receiving the series of values;
filtering the series of values;
monitoring the series of values and determining a signal value change within a predetermined period of time; and
passing through the received series of values or the filtered series of values depending on the determined signal value change within the predetermined period of time.

22. The method of claim 21, further comprising:
comparing the determined signal value change within the predetermined period of time with a threshold value and passing through the filtered series of values if the threshold value is not exceeded and passing through the received series of values if the threshold value is exceeded.

23. The method of claim 22, further comprising:
transmitting a current input signal value of the received series of values to a signal filter in case the received series of values is passed through and if, additionally, the signal value change falls below the threshold value, which results in passing through the filtered series of values.

24. The method of claim 22, further comprising:
clearing a signal filter if the signal value change falls below the threshold value, so that filtering is applied to newly received signal values only.

25. A power torque tool configured to apply a force to an object, comprising:
a signal filtering device according to claim 14.

26. The power torque tool of claim 25, further comprising:
a driving shaft configured to rotate and to apply a torque force to the object; and
a force measuring device configured to measure a force applied to the driving shaft,
wherein the signal filtering device is connected to the force measuring device and is configured to receive a force measuring signal from the force measuring device and to filter the force measuring signal.
